(19) United States
(12) Patent Application Publication
(10) Pub. No.: US 2015/0340230 A1
(43) Pub. Date: Nov. 26, 2015

(54) III NITRIDE EPITAXIAL SUBSTRATE AND METHOD OF PRODUCING THE SAME

(71) Applicant: DOWA ELECTRONICS MATERIALS CO., LTD., Chiyoda-ku, Tokyo (JP)

(72) Inventors: Tetsuya IKUTA, Akita-shi (JP); Tomohiko SHIBATA, Akita-shi (JP)

(21) Appl. No.: 14/759,128

(22) PCT Filed: Nov. 28, 2013
(86) PCT No.: PCT/JP2013/007012

§ 371 Date: Jul. 2, 2015

(30) Foreign Application Priority Data
Jan. 4, 2013 (JP) 2013-000148

(51) Int. Cl. H01L 21/02; H01L 29/20; H01L 29/15

(52) U.S. Cl. CPC H01L 21/02507; H01L 29/155; H01L 29/2003; H01L 21/02381; H01L 21/02458

(57) ABSTRACT

A III nitride epitaxial substrate with reduced warp after the formation of a main laminate and improved vertical breakdown voltage, and a method of producing the same, a III nitride epitaxial substrate includes: a Si substrate; an initial layer in contact with the Si substrate; and a superlattice laminate formed on the initial layer, the superlattice laminate including first layers made of Al_{α}Ga_{1-α}N (0.5<α≦1) and second layers made of Al_{β}Ga_{1-β}N (0<β≦0.5) that are alternately stacked, in which a composition ratio β of the second layers gradually increases as a distance from the Si substrate increases.

### TECHNICAL FIELD

This disclosure relates to a III epitaxial substrate and a method of producing the same.

### BACKGROUND

In recent years, III nitride semiconductors generally made of compounds in which N is combined with Al, Ga, In, and the like are widely used for light emitting devices, elements for electronic devices, and the like. The characteristics of such devices greatly depend on the crystallinity of III nitride semiconductors; therefore, techniques for growing highly crystalline III nitride semiconductors are demanded.

III nitride semiconductors have conventionally been formed by epitaxial growth on sapphire substrates. However, sapphire substrates have poor heat dissipation due to low thermal conductivity, which is not suitable for making high power output devices.

In order to address this problem, in recent years, techniques of using silicon substrates (Si substrates) as substrates for the crystal growth of III nitride semiconductors have been proposed. Si substrates have higher heat dissipation than the above sapphire substrates, so that they are suitable for making high power output devices. Further, since large silicon substrates are inexpensive, they are advantageous in reducing production cost. However, as with sapphire substrates, Si substrates have different lattice constants from III nitride semiconductors. Therefore, growing of a III nitride semiconductor directly on such a Si substrate is not expected to provide a highly crystalline III nitride semiconductor.

Further, a III nitride semiconductor has a high thermal expansion coefficient as compared with Si. Accordingly, in a case where this III nitride semiconductor is grown directly on a Si substrate, great tensile strain occurs in the III nitride semiconductor in the process of cooling from the high temperature of a crystal growth process to room temperature. This leads to problems of warpage of the Si substrate and the formation of high-density of cracks in the III nitride semiconductor.

JP 2007-067077 A (PTL 1) discloses a technique of producing a highly crystalline III nitride semiconductor, in which crack formation is prevented, on a Si substrate by providing an AlN-based superlattice buffer layer, in which a plurality of first layers made of AlₓGa₁₋ₓN (0.5≦x≦1) and a plurality of second layers made of Al_{y}Ga_{1-y}N (Al content y: 0.01≦y≦0.2) are alternately stacked, between the Si substrate and the III nitride semiconductor.

### CITATION LIST

### Patent Literature

PTL 1: JP 2007-067077 A

### SUMMARY

### Technical Problem

PTL 1 refers to the prevention of the formation of cracks in a III nitride semiconductor layer (main laminate) by forming a nitride semiconductor superlattice structure thereunder. However, the studies made by the inventors of the present invention found that when a conventional superlattice laminate as in PTL 1 is formed on a Si substrate and a main laminate including a III nitride semiconductor layer is formed thereon, the resulting III nitride epitaxial substrate would greatly warp with the Si substrate side being a concave and with the main laminate side being convex. Note that with respect to the warpage of a III nitride epitaxial substrate, hereinafter, warping with the Si substrate side being concave and with the main laminate side being convex is referred to as “warping convexly”, whereas warping with the Si substrate side being convex and with the main laminate side being concave is referred to as “warping concavely”. The formation of such a concave warp would hinder accurate working in a step of device formation using the main laminate, leading to the occurrence of device defects.

Further, there is a need for the improvement in the vertical breakdown voltage of the III nitride epitaxial substrate.

In view of the above problems, it could therefore be helpful to provide a III nitride epitaxial substrate with reduced warp after the formation of a main laminate and improved vertical breakdown voltage, and to provide a method of producing the same.

### Solution to Problem

A III nitride epitaxial substrate of this disclosure that makes it possible to achieve the above objective includes: a Si substrate; an initial layer in contact with the Si substrate; and a superlattice laminate formed on the initial layer, the superlattice laminate including first layers made of Al_{α}Ga_{1-α}N (0.5<α≦1) and second layers made of Al_{β}Ga_{1-β}N (0<β≦0.5) that are alternately stacked, in which an Al compo sition ratio β of the second layers gradually increases as a distance from the Si substrate increases.

Preferably, the superlattice laminate includes a plurality of superlattice layers in which the first layers and the second layers having a fixed Al composition ratio β are alternately stacked, and the second layers have larger Al composition ratio β as the superlattice layers including the second layers are positioned farther from the Si substrate.

It is also preferable that the difference between an Al composition ratio x of the second layer closest to the Si substrate and an Al composition ratio y of the second layer farthest from the Si substrate, y−x, is 0.02 or more.

Further, the first layers are preferably made of AlN.

Preferably, the initial layer includes an AlN layer and an Al_{z}Ga_{1-z}N layer (0<z<1) on the AlN layer, and an Al composition ratio z of the Al_{z}Ga_{1-z}N layer is larger than an Al composition ratio y of the second layer farthest from the Si substrate.

Preferably, the III nitride epitaxial substrate further includes, on the superlattice laminate, a main laminate formed by epitaxially growing III nitride layers including at least two layers consisting of an AlGaN layer and a GaN layer.

The warpage of the III nitride epitaxial substrate after the formation of the main laminate is equal to or less than the value given by the expression (1),

(x/6)²×50 μm (1),

wherein x is the inch size of the Si substrate. For example, when the

Si substrate is 6 inches in size, the warpage of the III nitride epitaxial substrate after the formation of the main laminate is preferably 50 μm or less.

A method of producing a III nitride epitaxial substrate of this disclosure includes a first step of forming an initial layer on a Si substrate in contact therewith; and a second step of forming, on the initial layer, a superlattice laminate in which first layers made of Al_{α}Ga_{1-α}N (0.5<α1) and second layers made of Al_{β}Ga_{1-β}N (0<β≦0.5) are alternately stacked, in which an Al composition ratio β of the second layers is gradually increased as the distance from the Si substrate increases in the second step.

### Advantageous Effect

The Al composition ratio β of the second layers being gradually increased as the distance from the Si substrate reduces the warpage of the III nitride epitaxial substrate after the formation of the main laminate, thereby obtaining the III nitride epitaxial substrate with improved vertical breakdown voltage.

### BRIEF DESCRIPTION OF THE DRAWINGS

In the accompanying drawings,

FIG. 1 is a schematic cross-sectional view of a III nitride epitaxial substrate 10;

FIG. 2 is a schematic cross-sectional view of another III nitride epitaxial substrate 20; and

FIG. 3 is a schematic cross-sectional view of a substrate for illustrating the definition of warpage (SORI).

### DETAILED DESCRIPTION

Our III nitride epitaxial substrates and methods will be now described with reference to the drawings in detail. Note that in the context of this disclosure, components that are common to two III nitride epitaxial substrates in embodiments of this disclosure are denoted by reference numerals having the same last two digits, and thus their descriptions will be omitted. Further, in the schematic cross-sectional views of the substrates, the thicknesses of the layers are exaggerated relative to the Si substrate for the sake of explanation. The term “AlGaN” alone herein means a compound having a chemical composition ratio of III elements (Al and Ga in total) with respect to N of 1:1 and any given ratio between the III elements of Al and Ga. Further, the ratio of Al in the III elements in the compound is referred to as “Al composition ratio”.

### Embodiment 1: III Nitride Epitaxial Substrate 10

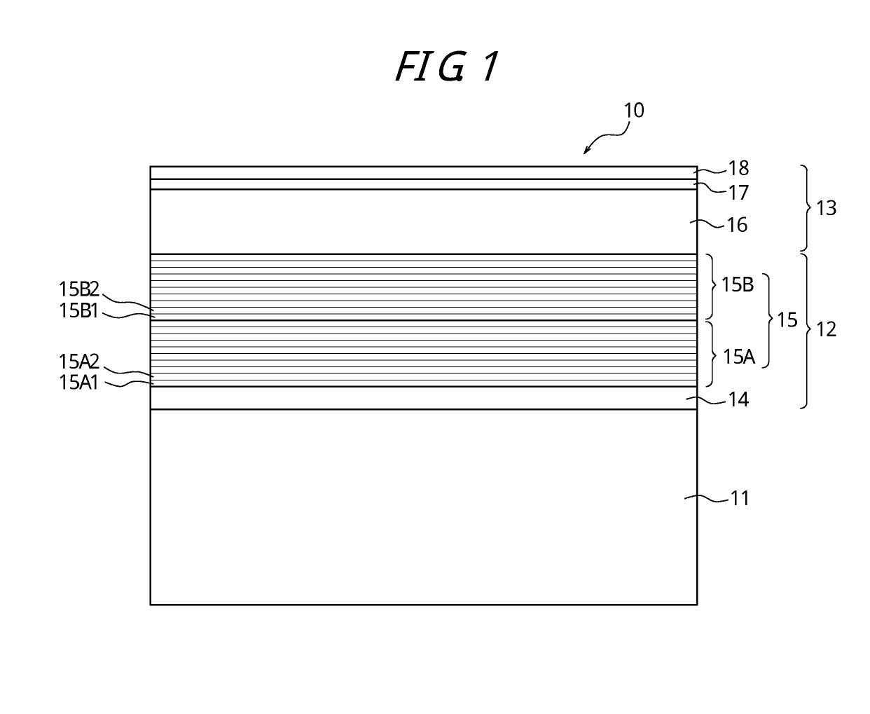

The III nitride epitaxial substrate 10 which is one of the disclosed embodiments has a Si substrate 11 and a buffer layer 12 formed on the Si substrate 11 as shown in FIG. 1. The III nitride epitaxial substrate 10 can include a main laminate 13 formed by epitaxially growing III nitride layers on the buffer layer 12. The buffer layer 12 has an initial layer 14 in contact with the Si substrate 11 and a superlattice laminate 15 formed on the initial layer 14 by alternately stacking first layers made of Al_{α}Ga_{1-α}N (0.5<α1) and second layers made of Al_{β}Ga_{1-β}N (0<β≦0.5). In this embodiment, the superlattice laminate 15 has two superlattice layers consisting of a first superlattice layer 15A and a second superlattice layer 15B. In the first superlattice layer 15A, first layers 15A1, for example made of AlN (α=1) and second layers 15A2 made of Al_{0.10}Ga_{0.90}N having a fixed Al composition β value of 0.10 are alternately stacked. In the second superlattice layer 15B, first layers 15B1, for example made of AlN (α=1) and second layers 15B2 made of Al_{0.15}Ga_{0.85}N having a fixed Al composition ratio β value of 0.15 are alternately stacked.

The Si substrate 11 is a Si single crystal substrate having any plane orientation; for example, the (111) plane, (100) plane, (110) plane, or the like can be used. However, in order to grow the (0001) plane of the III nitride, the (110) and (111) planes are desirable, and in order to grow the III nitride with favorable surface flatness, the (111) plane is desirably used. Further, either p-type or n-type of conductivity may be used, and any value of resistivities of 0.001 Ω·cm to 100000 Ω·cm is applicable. Here, the Si substrate may contain impurities (C, O, N, Ge, etc.) added for the purpose of other than controlling electrical conductivity. The thickness of the substrate is determined as appropriate considering, for example, the warpage of the layers after the epitaxial growth. For example, the thickness is within the range of 500 μm to 2000 μm.

Examples of typical materials for the initial layer 14 include AlGaN and AlN. Particularly when a portion of the initial layer 14 in contact with the substrate is an AlN layer, reaction with the Si substrate 11 can be suppressed, thereby improving the vertical breakdown voltage. The initial layer 14 does not necessarily have a uniform composition in the thickness direction. When a portion thereof in contact with the substrate is an AlN layer, the initial layer 14 may be a laminate of a plurality of layers having different compositions, or its composition can be graded. For example, an AlGaN layer may be formed on the AlN layer. Further, a thin film of nitride, oxide, carbide, or the like of Si, or a thin film obtained by reaction of AlN with such a film may be inserted at the interface portion between AlN and the Si single crystal substrate. Moreover, for the initial layer 14, for example, an amorphous layer or a polycrystalline layer such as a low temperature buffer layer may be formed with a thickness which does not impair crystal quality. The thickness of the initial layer 14 is for example within the range of 10 nm to 500 nm. When the thickness is less than 10 nm, Ga that is part of the materials of the upper layer would react with the Si substrate, resulting in defects. Whereas the thickness exceeds 500 nm, cracks would be formed at the time when the initial layer is formed.

This embodiment has a characteristic structure in which the Al composition ratio β of the second layers 15A2 in the first lattice layer 15A is 0.10, and the Al composition ratio β of the second layers 15B2 in the second superlattice layer 15B is 0.15, where the Al composition ratio β of the second layers increases as the distance from the Si substrate 11 increases. The inventors found that for such a superlattice laminate of AlGaN layers (AlN being included) having a high Al composition ratio a and AlGaN layers having a low Al composition ratio β, the warpage of the III nitride epitaxial substrate 10 after the formation of the main laminate β can be reduced by increasing the Al composition ratio β of the AlGaN layers having a low Al composition ratio β as the distance from the Si substrate increases. This can reduce the possibility of device defects in the step of device formation using the main laminate.

The inventors expect that the above effects can be achieved by the operation described below. That is, forming a layer having a high Al composition ratio on a layer having a low Al composition ratio is, in terms of the lattice constant of the wafer plane, forming a layer having a small in-plane lattice constant (for example AlN=3.11) on a layer having a large in-plane lattice constant (for example, GaN=3.19), which results in the induction of stretching stress to the layer having a high Al composition ratio. Further, when the layer having a low Al composition ratio is formed on the layer having a high Al composition ratio to which the stretching stress induced; conversely, the compressive stress is induced to the layer having a low Al composition ratio. Therefore, those stresses are weak in a simple repeated structure, since they cancel each other out. However, in a superlattice laminate of AlGaN layers (AlN being included) having a high Al composition ratio and AlGaN layers having a low Al composition ratio, when the Al composition ratio of the AlGaN layer having a low Al composition ratio is increased as the distance from the Si substrate increases, the lattice constant difference can be reduced, which results in the generation of stretching stress. The resulting stretching stress cancels out the compressive stress generated in the other layer, which makes it possible to reduce the total film stress. Thus, the superlattice laminate 15 can cancel out the stress between itself and the main laminate β, so that the warpage of the III nitride epitaxial substrate 10 after the formation of the main laminate β can be reduced.

Further, this embodiment, in which the Al composition ratio β of the second layers increases as the distance from the Si substrate 11 increases, is also effective in improving the vertical breakdown voltage as compared with the case where the Al composition ratio of the second layers decreases to the contrary as the distance from the Si substrate increases. The larger the Al composition ratio of a III nitride semiconductor is, the larger is the band gap, which leads to the increase in the inherent resistance that the material has. In this embodiment, since the layers having a high Al composition ratio are used in the lattice layer at a higher ratio, the resistance of the buffer layer can be increased, which is believed to cause the leakage current reduction effect and the breakdown voltage improvement effect. However, the total compressive stress generated in the superlattice laminate being too high leads to the formation of cracks. Therefore, the composition difference needs to be appropriately determined.

The main laminate 13 is formed, on the buffer layer 12, by epitaxially growing III nitride layers including at least two layers of an Al GaN layer and a GaN layer. In this embodiment, the main laminate 13 includes: a AlGaN layer 16 formed on the second superlattice layer 15B; a channel layer 17 made of GaN, formed on the AlGaN layer 16; and an electron supply layer 18 made of AlGaN having a larger band gap than the channel layer, formed on the channel layer 17. To prevent alloy scattering at a portion where a two-dimensional electron gas is generated, the GaN layer in the main laminate 13 is preferably located on the side closest to the electron supply layer 18 as in this embodiment. The layer immediately above the superlattice laminate 15 is preferably made of AlGaN or GaN having a lower Al composition ratio than the uppermost second layer in the superlattice laminate 15, such that compressive stress is applied to the layer. The thickness of the main laminate 13 is preferably within the range of 0.1 μm to 5 μm. The thickness being less than 0.1 μm would cause defects such as pits, whereas the thickness exceeding 5 μm would cause cracks in the main laminate 13. The thicknesses of the channel layer 17 and the electron supply layer 18 can be suitably determined depending on the device design.

The III nitride epitaxial substrate 10 of this embodiment can be used for any electronic device (LEDs, LDs, transistors, diodes, or the like). It is preferably used particularly for HEMTs (high electron mobility transistors).

The steps for forming devices using the III nitride epitaxial substrate 10 include a step of forming electrodes on the substrate 10, a step of forming grooves by etching for the singulation of the nitride semiconductor layer, a step of forming a surface passivation film, and a step of isolating the devices. The devices are transferred between the steps.

### Embodiment 2: III Nitride Epitaxial Substrate 20

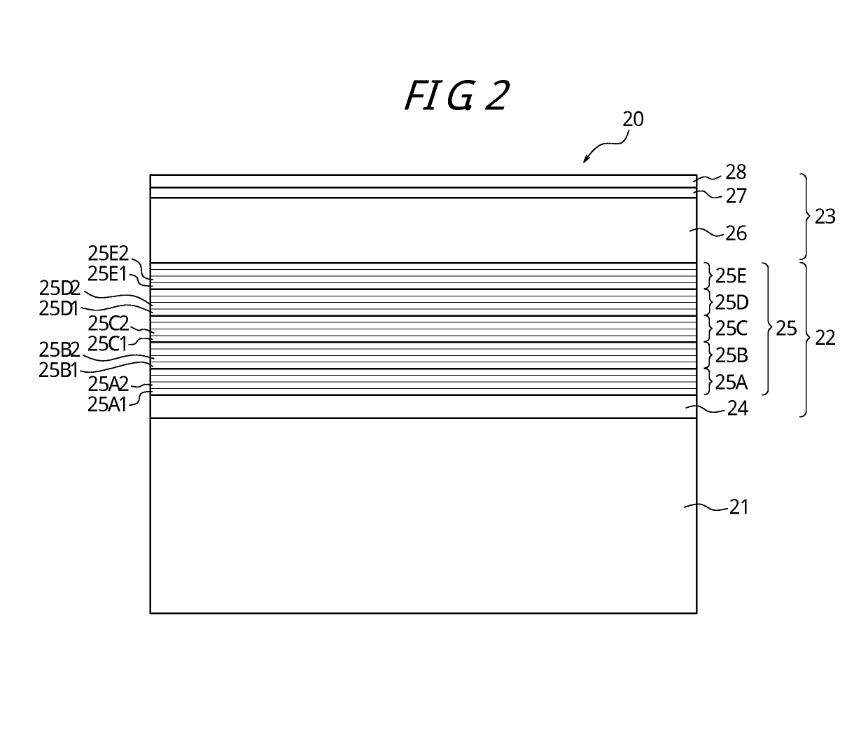

The III nitride epitaxial substrate 20 which is another embodiment of this disclosure has a Si substrate 21 and a buffer layer 22 formed on the Si substrate 21 as shown in FIG. 2. The III nitride epitaxial substrate 20 can include a main laminate 23 formed by epitaxially growing III nitride layers on the buffer layer 22. The buffer layer 22 has an initial layer 24 in contact with the Si substrate 21 and a superlattice laminate 25 formed on the initial layer 24 by alternately stacking first layers made of Al_{α}Ga_{1-α}N (0.5<α≦1) and second layers made of Al_{β}Ga_{1-β}N (0<β≦0.5). In this embodiment, the superlattice laminate 25 has five superlattice layers consisting of a first superlattice layer 25A, a second superlattice layer 25B, a third superlattice layer 25C, a fourth superlattice layer 25D, and a fifth superlattice layer 25E. In the first superlattice layer 25A, first layers 25A1, for example made of (α=1) and second layers 25A2 made of Al_{0.10}Ga_{0.90}N having a fixed Al composition 13 value of 0.10 are alternately stacked. In the second superlattice layer 25B, first layers 25B1, for example made of AlN (α=1) and second layers 25B2 made of Al_{0.12}Ga_{0.88}N having a fixed Al composition ratio β value of 0.12 are alternately stacked. In the third superlattice layer 25C, first layers 25C1, for example made of AlN (α=1) and second layers 25C2 made of Al_{0.14}Ga_{0.86}N having a fixed Al composition 13 value of 0.14 are alternately stacked. In the fourth superlattice layer 25D, first layers 25D1, for example made of AlN (α=1) and second layers 25D2 made of Al_{0.16}Ga._{0.84}N having a fixed Al composition ratio β value of 0.16 are alternately stacked. In the fifth superlattice layer 25E, first layers 25E1, for example made of AlN (α=1) and second layers 25E2 made of Al_{0.18}Ga_{0.82}N having a fixed Al composition ratio β value of 0.18 are alternately stacked.

Also in this embodiment, the Al composition ratios β of the second layers 25A2 to 25E2 in the five lattice layers 25A to 25E increase as 0.10<0.12<0.14<0.16<0.18 as the distance from the Si substrate 21 increases. Further, as in Embodiment 1, the warpage of the III nitride epitaxial substrate 20 after the formation of the main laminate 23 can be reduced and the vertical breakdown voltage can be improved.

The Si substrate 21, the initial layer 24, an AlGaN layer 26, a channel layer 27, and an electron supply layer 28 are the same as those in Embodiment 1.

### Other Embodiments

The above shows only examples of exemplary embodiments, and this disclosure is not limited to those embodiments and also includes, for example, the embodiments descried below.

Embodiments 1 and 2 show examples of providing a plurality of lattice layers in the superlattice laminates 15 and 25, in which the first layers of each lattice layer is made of AlN and the fixed Al composition ratios β of the second layers made of Al_{β}Ga_{1-β}N in each superlattice layer are increased as the distance from the substrate increases. Alternatively, the variation of the Al composition ratio in the superlattice laminate may be as descried below.

For example, for a superlattice laminate in which a plurality of sets of alternately stacked first layers made of AlN and second layers made of Al_{β}Ga_{1-β}N, the Al composition ratio β of the second layers may be gradually increased as the distance from the substrate increases. The gradual increase refers to the continuous or stepwise increase, including the continuous increase in the Al composition ratio β of the second layers as the distance from the Si substrate increases, other than the stepwise increase in the Al composition ratio β of the second layers due to the above plurality of superlattice layers. Even in such cases, it is obvious that the operation and effect described in Embodiment 1 can be achieved.

The second layers in this disclosure have an Al composition ratio β of 021 β≦0.5, and the first layers have an Al composition ratio a of 0.5<α≦1, so that any of the second layers always have a lower Al composition ratio than the first layers irrespective of whether the distance from the device is small or large. Accordingly, the first layers are not necessarily limited to the same composition (Embodiments 1 and 2) regardless of the distance from the device, and the Al composition ratio of the plurality of first layers may be varied within the range of 0.5<α≦1.

However, in this disclosure, all the first layers are preferably made of AlN as shown in Embodiments 1 and 2. Thus, the difference between the Al composition ratios of each of the first layers and the adjacent second layer is maximized, and the strain buffering effect is maximized.

The second layers are not limited in particular as long as the Al composition ratio β is 0<β≦0.5; however, is it preferable that the Al composition ratio y of the second layer farthest from the Si substrate is within the range of 0.05 to 0.5. The Al composition ratio y being less than 0.05 would make it impossible to ensure sufficient vertical breakdown voltage, whereas the Al composition ratio y exceeding 0.5 would lead to the formation of cracks in the superlattice laminate due to the insufficient strain buffering effect.

Further, the Al composition ratio x of the second layer closest to the Si substrate is never 0. In other words, the second layer is never GaN. This is because when the second layer is GaN, sufficient vertical breakdown voltage of the device cannot be ensured. Further, when the vertical breakdown voltage is particularly important, in terms of ensuring sufficient vertical breakdown voltage of the device as described above, x is preferably more than 0.05 and more preferably 0.10 or more.

For the Al composition ratio x of the second layer closest to the Si substrate and the Al composition ratio y of the second layer farthest from the Si substrate, x<y within the Al composition ratio β and the difference (y−x) is preferably 0.02 or more. The difference being less than 0.02 would lead to insufficient warpage reduction effect. Further, the difference (y−x) is preferably 0.45 or less, more preferably 0.2 or less.

When the initial layer 14 includes an AlN layer and an Al_{z}Ga_{1-z}N layer (0<z<1) on the AlN layer, the Al composition ratio z is preferably higher than the Al composition ratio y of the second layer farthest from the Si substrate, that is, the second layer having the highest Al composition ratio of the second layers. The relation z>y can suppress the formation of cracks in the superlattice laminate.

The “AlGaN” included in the buffer layer herein may contain other III elements, B and/or In, up to a total amount of 1% or less. Further, the “AlGaN” may contain a slight amount of impurities such as Si, H, O, C, Mg, As, or P. Note that GaN, AlGaN, and the like that form the main laminate may also contain other III elements up to a total amount of 1%.

The thickness of one stack in the superlattice laminate (a set of a first layer and a second layer in Embodiments 1 and 2) may be appropriately determined depending on the combination of the compositions, for example, may be approximately 1 nm to 100 nm. The thickness of the first layer may be 0.5 nm to 200 nm, and the thickness of the second layer may be 0.5nm to 100 nm.

The number of stacks in the superlattice laminate (sets of the first layers and second layers) may be determined depending on the required breakdown voltage, for example, may be 40 sets to 300 sets. Further, the thickness of the whole superlattice laminate is preferably 1 μm or more. The thickness being 1 μm or more leads to sufficiently large total stress generated in the film, so that the intended effects are sufficiently achieved.

The warpage of the III nitride epitaxial substrate after the formation of the main laminate is equal to or less than the value given by the expression (1),

(x/6)²×50 μm (1),

wherein x is the inch size of the Si substrate. For example, when the

Si substrate is 6 inches in size, the warpage of the III nitride epitaxial substrate after the formation of the main laminate is preferably 50 μm or less. This can more effectively reduce device defects in the step of device formation using the main laminate.

(Method of Producing III Nitride Epitaxial Substrate)

Embodiments of a method of producing a III nitride epitaxial substrate of the present invention will now be described. For example as shown in FIG. 1 A, a method of producing a III nitride epitaxial substrate according to this disclosure comprises: a first step of forming an initial layer 14 on a Si substrate 11 in contact therewith; and a second step of forming, on the initial layer 14, a superlattice laminate 15 in which first layers 15A1 (15B1) made of Al_{α}Ga_{1-α}N (0.5<α≦1) and second layers 15A2 (15B2) made of Al_{β}Ga_{1-β}N (0<β≦0.5) are alternately stacked, in which in the second step, an Al composition ratio β of a second superlattice layer 15B is higher than that of a first superlattice layer 15A, in other words, the Al composition ratio β of the second layers is gradually increased as the distance from the Si substrate 11 increases. After that, a main laminate 13 can be formed by epitaxially growing III nitride layers on the buffer layer 12. This method can reduce the warpage of the III nitride epitaxial substrate 10 after the formation of the main laminate 13 and can improve the vertical breakdown voltage.

Well-known methods such as MOCVD or MBE can be used for epitaxially growing each layer. Examples of a source gas used in the case of forming AlGaN include TMA (trimethylaluminum), TMG (trimethylgallium), and ammonia. The Al composition ratio of each layer can be adjusted by controlling the mixing ratio of TMA and TMG. Further, for the evaluation of the Al composition ratio and the layer thickness after the epitaxial growth, a well-known method such as TEM-EDS can be used.

The III epitaxial substrate and the method of this disclosure will be described in more detail below using examples. However, this disclosure is not limited to the following examples.

### EXAMPLES

### Example 1

An initial layer in which AlN (thickness: 120 nm) and Al_{0.35}Ga_{0.65}N (thickness: 50 nm) were sequentially stacked was formed as a buffer layer on a 6 inch p-type Si (111) single crystal substrate (B-doped, specific resistance: 0.02 Ω·cm, thickness: 625 μm). After that, a first superlattice layer in which 50 sets of AlN (thickness: 3.5 nm) and Al_{0.10}Ga_{0.90}N (thickness: 25 nm) were alternately stacked and a second superlattice layer in which 50 sets of AlN (thickness: 3.5 nm) and Al_{0.15}Ga₀₈₅N (thickness: 25 nm) were alternately stacked were sequentially epitaxially grown on the initial layer, thus forming a superlattice laminate. Subsequently, Al_{0.15}Ga_{0.85}N (thickness: 1 μm), a GaN channel layer (thickness: 20 nm), and an Al_{0.25}Ga_{0.75}N electron supply layer (thickness: 30 nm) were epitaxially grown as a main laminate on the superlattice laminate. Thus, a III nitride epitaxial substrate having a HEMT structure as in Embodiment 1 was fabricated. As the growth method, MOCVD using TMA (trimethylaluminum), TMG (trimethylgallium), and ammonia as source materials was used. Nitrogen and hydrogen were used for the carrier gas. The growth conditions (pressure and temperature) of each layer were 20 kPa, 1000° C., and a V/III ratio of 2000. The Al composition ratios of the AlGaN layers were controlled by appropriately controlling the mixing ratio between TMA and TMG. This also applies to the following Examples and Comparative Examples.

### Example 2

A III nitride epitaxial substrate having a HEMT structure as in Embodiment 2 was fabricated in the same manner as Example 1, except that the superlattice laminate was formed by sequentially epitaxially growing a first superlattice layer in which 20 sets of AlN (thickness: 3.5 nm) and Al_{0.10}Ga_{o 90}N (thickness: 25 nm) were alternately stacked, a second superlattice layer in which 20 sets of AlN (thickness: 3.5 nm) and Al_{o 12}Ga_{0.88}N (thickness: 25 nm) were alternately stacked, a third superlattice layer in which 20 sets of AlN (thickness: 3.5 nm) and Al_{o i4}Ga_{0.85}N (thickness: 25 nm) were alternately stacked, a fourth superlattice layer in which 20 sets of AlN (thickness: 3.5 nm) and Al_{0.16}Ga_{0.84}N (thickness: 25 nm) were alternately stacked, and a fifth superlattice layer in which 20 sets of AlN (thickness: 3.5 nm) and Al_{0.18}Ga_{0.82}N (thickness: 25 nm) were alternately stacked. The growth temperature and the growth pressure were the same as in Example 1.

### Example 3

A III nitride epitaxial substrate having a HEMT structure was fabricated in the same manner as Example 1, except that the superlattice laminate was formed by sequentially epitaxially growing a first superlattice layer in which 20 sets of AlN (thickness: 3.5 nm) and Al_{0.10}Ga_{0.90}N (thickness: 25 nm) were alternately stacked, a second superlattice layer in which 20 sets of AlN (thickness: 3.5 nm) and Al_{0.1}Ga_{0.89}N (thickness: 25 nm) were alternately stacked, a third superlattice layer in which 20 sets of AlN (thickness: 3.5 nm) and Al_{0.12}Ga_{0.88}N (thickness: 25 nm) were alternately stacked, a fourth superlattice layer in which 20 sets of AlN (thickness: 3.5 nm) and Al_{0.13}Ga_{0.87}N (thickness: 25 nm) were alternately stacked, and a fifth superlattice layer in which 20 sets of AlN (thickness: 3.5 nm) and Al_{o 14}Ga_{o 86}N (thickness: 25 nm) were alternately stacked.

### Comparative Example 1

A III nitride epitaxial substrate having a HEMT structure according to Comparative Example 1 was fabricated in the same manner as Example 1, except that the superlattice laminate was epitaxially growing a superlattice layer in which 100 sets of AlN (thickness: 3.5 nm) and Al_{0.15}Ga_{0.85}N (thickness: 25 nm) were alternately stacked.

### Comparative Example 2

A III nitride epitaxial substrate having a HEMT structure according to Comparative Example 2 was fabricated in the same manner as Example 1, except that the superlattice laminate was epitaxially growing a superlattice layer in which 100 sets of AlN (thickness: 3.5 nm) and Al_{0.10}Ga_{0.90}N (thickness: 25 nm) were alternately stacked.

### Comparative Example 3

A III nitride epitaxial substrate having a HEMT structure according to Comparative Example 3 was fabricated in the same manner as Example 1, except that the superlattice laminate was epitaxially growing a superlattice layer in which 100 sets of AlN (thickness: 3.5 nm) and Al_{0.05}Ga_{0.95}N (thickness: 25 nm) were alternately stacked.

### Comparative Example 4

A III nitride epitaxial substrate having a HEMT structure according to Comparative Example 4 was fabricated in the same manner as Example 1, except that the superlattice laminate was epitaxially growing a superlattice layer in which 100 sets of AlN (thickness: 3.5 nm) and GaN (thickness: 25 nm) were alternately stacked.

### Comparative Example 5

A III nitride epitaxial substrate having a HEMT structure according to Comparative Example 5 was fabricated in the same manner as Example 1, except that the superlattice laminate was formed by sequentially epitaxially growing a first superlattice layer in which 50 sets of AlN (thickness: 3.5 nm) and Al_{0.1.0}Ga_{o 90}N (thickness: 25 nm) were alternately stacked and a second superlattice layer in which 50 sets of AlN (thickness: 3.5 nm) and Al_{0.05}Ga_{0.95}N (thickness: 25 nm) were alternately stacked.

### Comparative Example 6

A III nitride epitaxial substrate having a HEMT structure according to Comparative Example 6 was fabricated in the same manner as Example 1, except that the superlattice laminate was formed by sequentially epitaxially growing a first superlattice layer in which 50 sets of AlN (thickness: 3.5 nm) and Al_{0.15}Ga_{0.85}N (thickness: 25 nm) were alternately stacked and a second superlattice layer in which 50 sets of AlN (thickness: 3.5 nm) and Al_{0.10}Ga_{0.90}N (thickness: 25 nm) were alternately stacked.

(Evaluation 1: Measurement of warpage of III nitride epitaxial substrate)

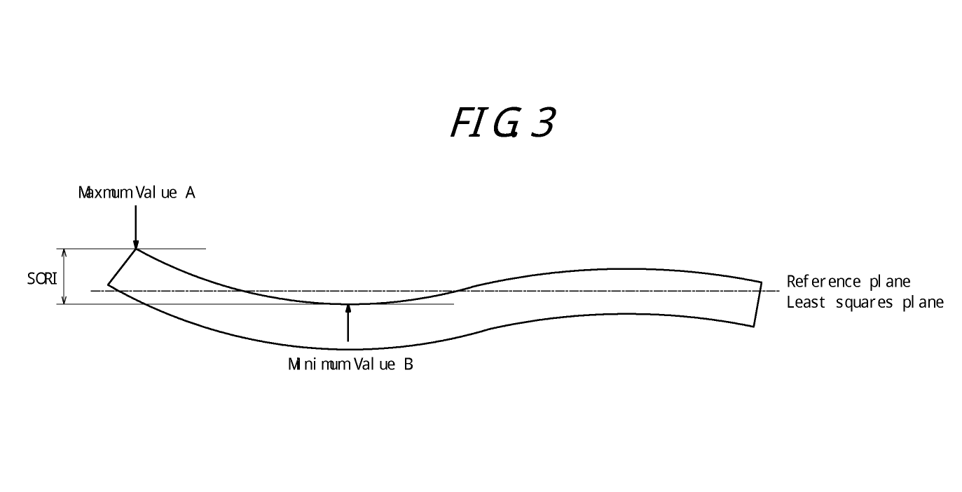

The warpage of each III nitride epitaxial substrate after the formation of the main laminate was measured using a warpage measurement system using optical interferometry (FT-900 manufactured by NIDEK CO., LTD.), and the results are shown in Table 1. The “warpage” herein is that measured in accordance SEMI M1-0302. Specifically, the warpage was performed in an unforced state, and the warpage is the value of the difference between the maximum and minimum values of the data of all the points of measurement for the wafer in an unchucked state. As shown in FIG. 3, provided that the reference plane is an imaginary plane found by the least squares method, the warpage (SORI) is represented by the sum of the absolute values of the maximum value A and the minimum value. Note that in Table 1 , the warp protruding downward from the reference plane is shown as “−(minus)”, whereas the warp protruding upward is shown as “+(plus)”.

(Evaluation 2: Measurement of vertical breakdown voltage)

An ohmic electrode having a Ti/Au laminate structure with a diameter of 80 μm is formed on the electron supply layer, and the outside of the ohmic electrode was etched by 50 nm deep. Subsequently, the back surface of the Si substrate was grounded to a metal plate, and the value of the current flowing between the electrodes was measured with respect to the voltage. On this occasion, in order to suppress electrical discharge in the air, insulation was made between the electrodes using insulating oil. Further, in order to eliminate the effect of the leakage to the back surface of the substrate, an insulating plate is placed under the substrate. In this example, the vertical breakdown voltage is the value of voltage at which the value of vertical current is converted into the value per unit area of the ohmic electrode reaches 10⁻⁴ A/cm², the results are shown with the following criteria in Table 1.

### (Criteria)

+: 400 V or more

−: 200 V or more and less than 400 V
−−: less than 200 V

TABLE 1

| | | Vertical |
|---|---|---|
| | Warpage | breakdown |
| | (μm) | voltage |
| Example 1 | −20 | + |
| Example 2 | −20 | + |
| Example 3 | −10 | + |
| Cooperative Example 1 | 150 | + |
| Cooperative Example 2 | 150 | + |
| Cooperative Example 3 | 120 | − |
| Cooperative Example 4 | 100 | −− |
| Cooperative Example 5 | 80 | − |
| Cooperative Example 6 | 60 | + |

As shown in Table 1, in Examples, the warpage of each III nitride epitaxial substrate after the formation of the main laminate was 50 μm or less, which is smaller than in Comparative Examples. Further, the Al composition ratio of the second layers in the superlattice laminate was higher as they are closer from the initial layer to the main laminate, so that the vertical breakdown voltage was not degraded as compared with Comparative Examples 5 and 6 in which the Al composition ratio of the second layers in the superlattice laminate was lower as they are closer from the initial layer to the main laminate.

Further, Example 1 and Example 2 show that the similar effect can be obtained even if a large number of changes are made on the Al composition ratio. Furthermore, comparing Example 2 and Example 3, the effect achieving the convex shape is found to be higher as the change in the Al composition ratio of the second layers is large.

### INDUSTRIAL APPLICABILITY

A III nitride epitaxial substrate with reduced warpage of the III nitride epitaxial substrate after the formation of the main laminate and with improved vertical breakdown voltage can be obtained.

### REFERENCE SIGNS LIST

10: III nitride epitaxial substrate

11: Si substrate

12: Buffer layer

13: Main laminate

14: Initial layer

15: Superlattice laminate

15A: First superlattice layer

15A1: First layer (AlN)

15A2: Second layer (Al_{0.10}Ga_{0.90}N)

15B: Second superlattice layer

15B1: First layer (AlN)

15B2: Second layer (Al_{0.15}Ga_{0.85}N)

16: AlGaN layer

17: Channel layer (GaN)

18: Electron supply layer (AlGaN)

1. A III nitride epitaxial substrate, comprising: a Si substrate; an initial layer in contact with the Si substrate; and a superlattice laminate formed on the initial layer, the superlattice laminate including first layers made of Al_{α}Ga_{1-α}N (0.5<α≦1) and second layers made of Al_{β}Ga_{1-β}N (0<β≧0.5) that are alternately stacked,
wherein an Al composition ratio β of the second layers gradually increases as a distance from the Si substrate increases.

2. The III nitride epitaxial substrate according to claim 1, wherein the superlattice laminate includes a plurality of superlattice layers in which the first layers and the second layers having a fixed Al composition ratio β are alternately stacked, and
the second layers have larger Al composition ratio β as the superlattice layers including the second layers are positioned farther from the Si substrate.

3. The III nitride epitaxial substrate according to claim 1, wherein the difference between an Al composition ratio x of the second layer closest to the Si substrate and an Al composition ratio y of the second layer farthest from the Si substrate, y−x, is 0.02 or more.

4. The III nitride epitaxial substrate according to claim 1, wherein the first layers are made of AlN.

5. The III nitride epitaxial substrate according to claim 1, wherein the initial layer includes an AN layer and an Al_{z}Ga_{1-z}N layer (0<z<1) on the AlN layer, and an Al composition ratio z of the Al_{z}Ga_{1-z}N layer is larger than an Al composition ratio y of the second layer farthest from the Si substrate.

6. The III nitride epitaxial substrate according to claim 1, further comprising, on the superlattice laminate, a main laminate formed by epitaxially growing III nitride layers including at least two layers consisting of an AlGaN layer and a GaN layer.

7. The III nitride epitaxial substrate according to claim 6, wherein the warpage of the III nitride epitaxial substrate after the formation of the main laminate is equal to or less than the value given by the expression (1),
(x/6)²×50 μm (1),
wherein x is the inch size of the Si substrate.

8. The III nitride epitaxial substrate according to claim 6, wherein the Si substrate is 6 inches in size, and the warpage of the III nitride epitaxial substrate after the formation of the main laminate is 50 μm or less.

9. A method of producing a III nitride epitaxial substrate, comprising:
a first step of forming an initial layer on a Si substrate in contact therewith; and
a second step of forming, on the initial layer, a superlattice laminate in which first layers made of Al_{α}Ga_{1-α}N (0.5<α≦1) and second layers made of Al_{β}Ga_{1-β}N (0<β≦0.5) are alternately stacked,
wherein an Al composition ratio β of the second layers is gradually increased as the distance from the Si substrate increases in the second step.
